(19) United States
(12) Patent Application Publication
(10) Pub. No.: US 2007/0128749 A1
(43) Pub. Date: Jun. 7, 2007

(54) Multicore Microstructured Optical Fibers for Imaging

(75) Inventors: Martijn Alexander Van Eijkelenborg, New South Wales (AU); Ian Kenneth Mann, New South Wales (AU); Francios Ladouceur, New South Wales (AU); Maryanne Candida Jane Large, New South Wales (AU)

Correspondence Address: MILLER, MATTHIAS & HULL, ONE NORTH FRANKLIN STREET, SUITE 2350, CHICAGO, IL, 60606, US

(73) Assignees: The University of Sydney, Sydney, New South Wales (AU); Bandwidth Foundry Pty Ltd., Eveleigh, New South Wales (AU)

(21) Appl. No.: 10/595,976

(22) PCT Filed: Nov. 24, 2004
(86) PCT No.: PCT/AU04/01639

§ 371 Date: May 23, 2006

(30) Foreign Application Priority Data
Nov. 24, 2003 (AU) 2003906499

(51) Int. Cl. H01L 21/00

(52) U.S. Cl. 438/29

(57) ABSTRACT

The present invention relates to the design and manufacture of microstructured optical fibres. The invention has particular application in the manufacture of microstructured optical fibres for imaging purposes such as, for example, endoscopy, ear-implants, and chip-to-chip interconnects. A first aspect of the invention provides a method of producing a microstructured optical fibre from a preform, said method including the steps of: creating zones of relatively high refractive index at predetermined locations in said preform, said zones substantially surrounded by material of relatively low refractive index to create an array of light guiding cores, and subsequently drawing said preform to create a length of said microstructured optical fibre. A second aspect of the invention provides a method of producing a microstructured optical fibre from a preform, said method including the steps of creating channels of relatively low refractive index at predetermined locations in said preform, said channels acting to define light guiding cores, and subsequently drawing said preform to create a length of said microstructured optical fibre.

### FIELD OF THE INVENTION

The present invention relates to the design and manufacture of microstructured optical fibres. The invention has particular application in the manufacture of microstructured optical fibres for imaging purposes such as, for example, endoscopy, ear-implants, and chip-to-chip interconnects.

### BACKGROUND TO THE INVENTION

In existing multicore fibres, light is guided through total internal reflection in cores of relatively high refractive index. Consequently, the imaging fibre has always been made from transparent material. The fabrication methods include stacking of capillaries and rods to make a preform, on bundling fibres, on complex doping techniques, or on co-extrusion. However, one of the difficulties encountered with these methods is maintaining the coherency of the fibre bundle and achieving adequate control over the position and size of individual cores (pixels), as well as obtaining a high capturing fraction.

It is therefore an object of the present invention to overcome or ameliorate at least one of the disadvantages of the prior art, or to provide a useful alternative.

### SUMMARY OF THE INVENTION

To this end, a first aspect of the present invention provides a method of producing a microstructured optical fibre from a preform wherein zones of material of relatively high refractive index are positioned at predetermined locations within material of relatively low refractive index. By creating “islands” of high-index material in a body of lower refractive index material a pattern of guiding cores is created. The preform is subsequently drawn to create a length of microstructured optical fibre.

Preferably, each core is surrounded substantially by air, and connected to other cores by thin strands of fibre material. This enables the cores to guide independently (provided the strands are thin and long enough) and thereby provide imaging capability. The cores may be either single moded or multi moded. The cross-sectional shape of the cores is generally non-circular.

A second aspect of the present invention provides a method of producing a microstructured optical fibre wherein hollow channels, or channels of relatively low refractive index material, are positioned at predetermined locations in a preform. The preform is subsequently drawn to create a length of microstructured optical fibre in which the low-index channels can guide light independently based on the ‘antiguiding’ effect as described in [“Identifying hollow waveguide guidance in air-cored microstructured optical fibres”, N A. Issa, A Argyros, M A. van Eijkelenborg, J Zagari, Optics Express Vol. 11, No. 9, pp. 996-1001 (2003).]

Advantageously, the method according to the second aspect of the invention allows for the manufacture of relatively simple interconnects and imaging fibres with a high capture fraction.

Preferably the fibre is drawn from a monolithic preform. This provides enhanced control and stability over the resulting fibre.

Advantageously, a combination of the first and second methods of imaging is also possible in certain circumstances, which would provide the largest possible capture fraction (since it uses both the low index channels and the high index cores for the imaging). This enhances the pixel resolution.

A third aspect of the present invention provides a micro-structured optical fibre which includes air channels, said air channels acting to define light guiding cores between the air channels.

A fourth aspect of the present invention provides a micro-structured optical fibre for imaging applications, said optical fibre including air channels which act as light guiding cores.

In this embodiment of the invention, the fibre may include non-transparent materials.

Advantageously, the present invention provides a relatively simple method of producing a microstructured optical fibre for imaging applications and which allows greater control over the positioning and sizing of the cores. Any pixel arrangement is generally possible, both in terms of symmetry (hexagonal, rectangular etc) and in terms of core dimensions (multiple core sizes in one fibre are possible), making it relatively easy to tailor the characteristics of the imaging fibre. In addition, the cores (whether they are of relatively high or low refractive index) need not all be of the same dimensions. Cores, or groups of cores, can be individually sized to specific dimensions as required for a particular application.

In addition, in a preferred embodiment the fibre is drawn from a monolithic holey preform (rather than a stacked preform), thereby providing further control and stability. Moreover, no doping is required to create guiding cores.

### BRIEF DESCRIPTION OF DRAWINGS

A preferred embodiment of the invention will now be described, by way of example only, with reference to the accompanying drawings in which:

FIG. 1 is a microscope image of the cross section of a microstructured polymer optical fibre;

FIG. 2 illustrates an imaging experiment utilising a microstructured optical fibre according to the present invention;

FIG. 3 is a CCD camera image of the exit face of a fibre subjected to uniform illumination (left image); and a CCD camera image of the exit face of a fibre which has been illuminated with an image of the letter “C” (right image);

FIG. 4 is a CCD camera image of the exit face of the fibre demonstrating an anti-guiding mode of operation;

FIG. 5 is a microscope image of a multicore optical fibre produced according to an aspect of the present invention; and

FIG. 6 is a graph illustrating the relationship between confinement losses and number of rings for the structure shown to the left of the graph, with the x-axis defining the ratio of hole diameter to spacing.

### DETAILED DESCRIPTION OF THE INVENTION

The various aspects of the present invention will be further described by way of the following example and with reference to the accompanying drawings. Whilst the fibre referred to in the following example was fabricated from polymeric material, it is to be noted that the principles underlying imaging capabilities are not specific to polymeric fibres, and other suitable material may be used.

A range of different fabrication methods can be used to make microstructured polymer optical fibre (“mPOF”) preforms. In addition to the capillary stacking technique, as is traditionally used for glass PCF, polymer preforms can be made using techniques such as extrusion, polymerisation in a mould, drilling or injection moulding. These methods provide advantages over bundling or stacking, since the hole pattern, size and spacing can be altered independently and no interstitial holes are created within the lattice. In addition, the creation of non-circular holes becomes relatively straightforward.

For the fabrication mPOFs that are presented in the following example, commercially available extruded polymethylmethacrylate (PMMA) rods of 80 mm diameter were used, which has a glass transition temperature Tg=115° C. A hole structure was drilled into an annealed PMMA cylinder of 80 mm diameter and 65 mm length using a computer-controlled facility, which is based on a programmable CNC mill optimised for mPOF preform fabrication. This provides complete control over the relative positioning and sizes of the holes. When required, the holes can be positioned very close together, leaving an inter hole wall thickness as thin as 0.1 mm.

The mPOF preform was drawn in a two-stage process. In the first stage, the 80 mm diameter structured preform was heated and stretched to a length of ˜2 metres to reduce the outer diameter from 80 mm to about 12 mm.

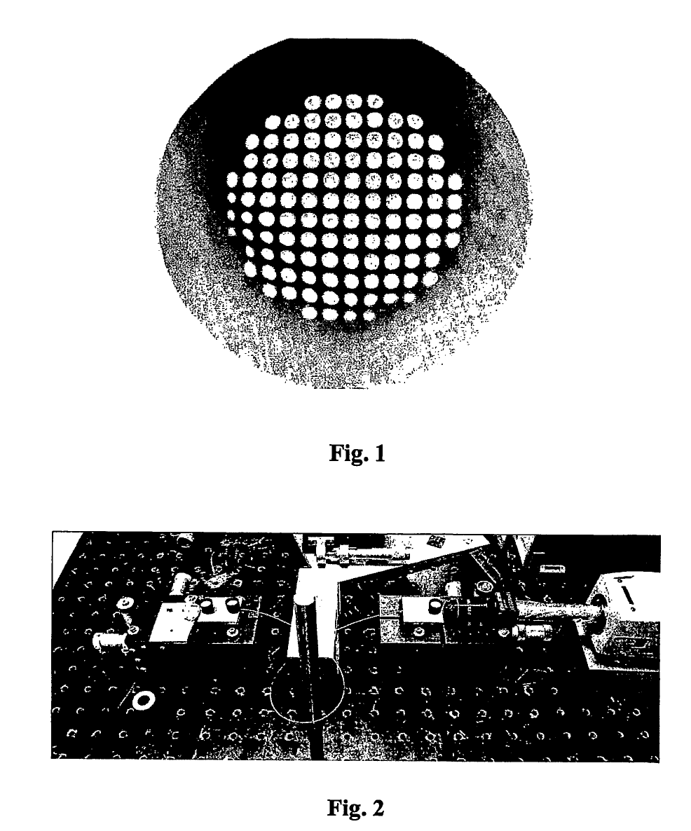

In a second stage, the 12 mm diameter preform was drawn to fibre on a separate computer-controlled polymer fibre draw tower. Fibre was drawn at a rate of 4 m/min at a constant tension of around 100 grams and a ‘hot-zone’ draw temperature of ˜160° C. The resulting mPOF structures, such as that shown in FIG. 1, are maintained over lengths of 100 m. Fibres are generally drawn to an external diameter of 200 microns, with a fibre diameter uniformity of ±1 micron achieved by utilisation of a well-tuned feedback control loop between the capstan speed and the fibre diameter monitor. A preform sleeving technique has been developed to provide fibres with a larger outer diameter whilst maintaining the same dimensions for the internal structure of the fibre, when required.

Referring to FIG. 1, a microscope image of the resulting microstructured polymer optical fibre is shown. The diameter of the fibre is 800 micron and the cross-section includes an array of evenly spaced air holes (112 holes in total at spacings of 42 microns) which provides the imaging function by guiding in between the air holes (solid cores), by antiguiding in the air holes, or both. A second, similar fibre was fabricated from the same preform with 250 micron diameter and 15 micron hole spacing.

To demonstrate the imaging capability of the solid-cores, a metal screen with a C shape cut out is placed in front of a white light source. FIG. 2 depicts an experiment wherein a metal screen with a cut out in the form of the letter C cut out was placed in front of a white light source. The screen was imaged onto one end of the fibre by means of a small lens (f˜5 mm). The fibre transmitted this image over its 42 cm length and the opposing end face of the fibre was imaged onto a CCD camera with a 10× microscope objective.

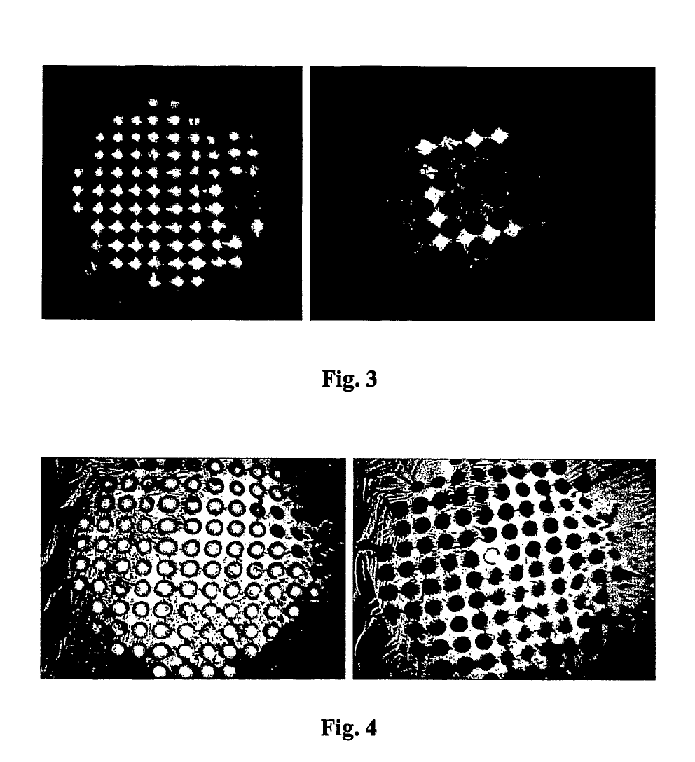

FIG. 3 illustrates the CCD camera image of the exit face of the fibre for uniform illumination (left) and the CCD camera image of the exit face of the fibre with the letter C screen in front of the white light source (right). It can clearly be seen that the cores in between the air holes have guided the image in a coherent way. This image is maintained under fibre bending, down to a bending radius of approximately 3 mm, beyond which the transmission losses become significantly higher (for the 250 micron diameter fibre).

Referring to FIG. 4, a CCD camera image of the exit face of the fibre is illustrated which demonstrates the second mode of operation of the fibre (antiguiding). This experiment was identical to the previous one, with the exception that it was performed with a 20 cm long piece of the 800 micron diameter fibre. The image on the left shows the result for uniform illumination. A slight blue colouration of some of the cores is common for the antiguiding mechanism (blue wavelengths are guided more efficiently in antiguides). The image on the right shows the result for imaging of a pinhole. When the pinhole is moved around, the bright spot in the image moves accordingly, demonstrating that the air channels act as individual guiding cores.

As mentioned above, one possible application is in relation to chip-to-chip connections. For high-speed computer chips that are operating at very high frequencies, small wires that connect the chips will act as antennas, and the electronic signals sent from one chip to another at such speeds would be distorted, radiated out or lost. Also, timing and synchronisation issues become important. This can potentially be overcome by having one chip drive something like a VCSEL array (a usually square array of Vertical Cavity Surface Emitting Lasers) producing a pattern of light beams that are all (individually) modulated to carry signals. This array of light is then captured by the microstructured imaging fibre, which has cores of appropriate sizes and positions to match the VCSEL array (either solid cores, hollow cores or both). The signals and transferred to the other end of the fibre where it is read out by a detector array of similar arrangement as the VSCEL array. The fibre can either be butt-coupled to the VCSEL array, with for example each hollow channel capturing the light from one VCSEL, or some imaging arrangement with a lens or multiple lenses can be placed in between the VCSELs and the fibre end.

A further possible application of the present invention is in relation to ear implants. Ear implants (such as developed by Cochlear Pty Ltd) consist of a fine electrode embedded in silicon which is to be implanted into the cochlear in order to directly stimulate the nerves and thereby recover some sense of hearing. One issue with implanting ear implants is that they are inserted without any visual image of the channel of the ear. Sometimes obstructions are encountered, and without a visual image of the obstruction, it cannot be determined how to get around it, or whether it is safe to go through it. Advantageously, the imaging mPOFs created by the present invention can be of such small dimensions, that they would be suitable to be incorporated into the silicone ear implant, and thereby provide an image from the tip of the implant as it is inserted.

A further aspect of the present invention will now be described.

Microstructured optical fibres allow the possibility of fabricating structures which contain multiple light guiding cores. This offers some important advantages for optical interconnects, principally because it allows the distance between fibre cores to be minimised, thus increasing the core packing density. This has key applications, of which one of the most important is the creation of a 2D array that could couple effectively to, for example an array of VCSELs.

Current fibre arrays are limited in packing density by the diameter of the fibre (typically 125 micron). Using microstrutured fibres this density can be greatly increased by the use of “fibres” that contain multiple cores. Additionally, tapering and/or shaping of these fibres can allow for the modes to be tailored in size and/or shape. This eliminates the current need to an intermediate structure between the VSCEL array and fibre buddle [eg. Polyguide™]. Furthermore, tapering of the entire multi-core structure eliminates the need for a separate fan out device.

There are two main approaches to the manufacturing of the multicore fibres. The first is to create a stackable structure with suitably isolated cores in the preform. The core structures in this case could extend right to the edge of the preform, or, if this causes problems for of distortion, the fibres could be subsequently trimmed by a secondary process. Arrays could then be assembled by stacking the fibres in a modular fashion. Alternatively, and probably preferably, the complete desired structure can be assembled by stacking capillaries and then drawing to fibre, as shown in FIG. 5. The difference between the processes is that in one case the structure is assembled at the capillary stage, and in the other at the fibre stage. These two processes can also be combined. The packing density for the capillary stacks however will be higher than for the fibre stacks, and will also eliminate the need for any latter assembly of the fibres to form an array. It is likely that capillaries or fibres with squared or rectangular cross sections will be preferred for VCSEL array applications.

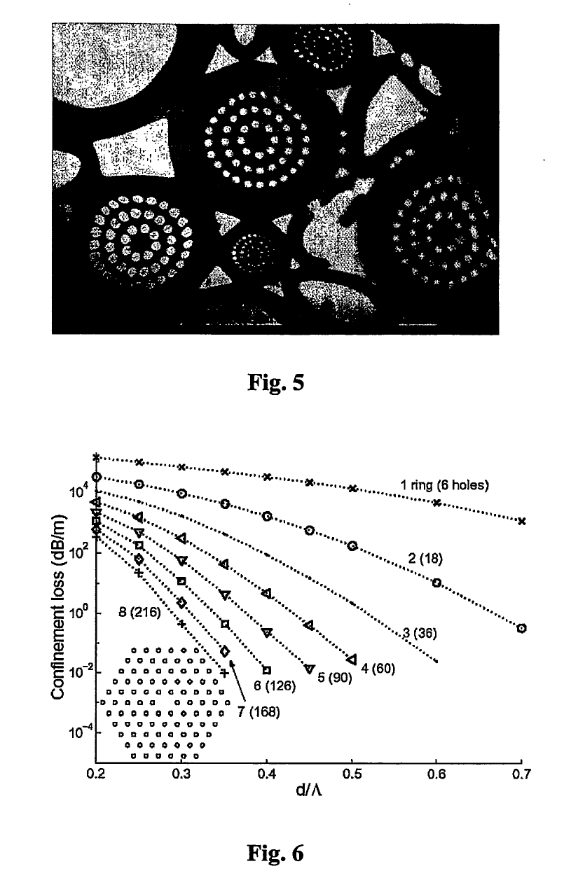

The spacing of the fibre cores is determined by the requirement that the confinement loss for the modes is small. This is determined by the number of rings and the air fraction, as shown in FIG. 6.

Although the invention has been described with reference to specific examples it will be appreciated by those skilled in the art that the invention may be embodied in many other forms.

1. A method of producing a microstructured optical fibre from a preform, said method including the steps of:
creating zones of relatively high refractive index at predetermined locations in said preform, said zones substantially surrounded by material of relatively low refractive index to create an array of light guiding cores, and
subsequently drawing said preform to create a length of said microstructured optical fibre.

2. The method as claimed in claim 1 wherein said light guiding cores are surrounded substantially by air.

3. The method as claimed in claim 1 or 2 wherein said light guiding cores have a generally non-circular cross-sectional shape.

4. The method as claimed in any one of claims 1 to 3 wherein said preform is formed from optically suitable polymeric material.

5. The method as claimed in any one of claims 1 to 3 wherein a plurality of holes is drilled into said preform at said predetermined locations.

6. The method as claimed in any one of claims 1 to 5 wherein said preform is drawn to form said microstructured optical fibre in a two-stage drawing process.

7. A method of producing a microstructured optical fibre from a preform, said method including the steps of:
creating channels of relatively low refractive index at predetermined locations in said preform, said channels acting to define light guiding cores, and
subsequently drawing said preform to create a length of said microstructured optical fibre.

8. The method as claimed in claim 7 wherein a plurality of holes is drilled into said preform at said predetermined locations to create said channels.

9. The method as claimed in claim 7 or 8 wherein said preform is drawn to form said microstructured optical fibre in a two-stage drawing process.

10. The method as claimed in any one of claims 7 to 9 wherein said preform is monolithic.

11. A micro-structured optical fibre, said optical fibre including a plurality of air channels, said air channels acting to define light guiding cores between said air channels.

12. A micro-structured optical fibre for imaging applications, said optical fibre including air channels which act as light guiding cores.
